(19) United States
(12) Patent Application Publication
(10) Pub. No.: US 2026/0292988 A1
(43) Pub. Date: Sep. 24, 2026

(54) CIRCUIT MODULE AND OPTICAL DEVICE

(71) Applicant: CANON KABUSHIKI KAISHA, Tokyo (JP)

(72) Inventors: MITSUTOSHI HASEGAWA, Kanagawa (JP); SATORU HIGUCHI, Tokyo (JP); HIDETO TAKAHASHI, Tokyo (JP); NORITAKE TSUBOI, Kanagawa (JP)

(21) Appl. No.: 19/564,829

(22) Filed: Mar. 12, 2026

(30) Foreign Application Priority Data
Mar. 19, 2025 (JP) 2025-045660

(51) Int. Cl. H05K 1/14; G03B 17/14; H04N 23/55; H05K 1/02; H05K 1/181

(52) U.S. Cl. CPC H05K 1/14; G03B 17/14; H04N 23/55; H05K 1/0284; H05K 1/181

(57) ABSTRACT

A circuit module includes a first wiring board including a first main surface and a second main surface, and a second wiring board including a third main surface intersecting with a direction along the first main surface. The first main surface and the second main surface of the first wiring board are soldered to the third main surface of the second wiring board. The third main surface of the second wiring board includes an overlapping portion overlapping with the first wiring board in a first direction orthogonal to the third main surface, a first portion extending from the overlapping portion on one side in a second direction orthogonal to the first direction, and a second portion extending from the overlapping portion on another side in the second direction. The circuit module further includes a plurality of electronic parts mounted on the second portion.

### BACKGROUND

### Field of the Technology

The present disclosure relates to a circuit module and an optical device.

### Description of the Related Art

In a camera system of a lens-interchangeable type, a circuit board including a wiring board and an electronic part mounted on the wiring board for realizing an auto-focus system or the like is provided in an optical device (interchangeable lens) coupled to a camera body. A wiring board having an annular shape or an arcuate shape so as not to block light is used as the wiring board because an optical system is also provided in the interchangeable lens.

In accordance with miniaturization of the camera body, improvement in image quality, and improvement in performance, the performance of the interchangeable lens has also been improved by miniaturization of electronic parts, shake correction, and the like. In addition, the circuit board disposed inside the interchangeable lens includes a system circuit on which semiconductor parts such as a central processing unit (CPU) are mainly mounted, and a driver circuit such as a power source. In such a circuit board, a large number of electronic parts including semiconductor parts and passive parts have come to be mounted on a wiring board in high density. In addition, regarding the wiring board, since the size of the wiring board is determined in accordance with the size, number, and arrangement of the electronic parts, the outer diameter of the lens on the inside of the wiring board is limited, or the outer diameter of the optical device increases. To realize an optical device having a small size and high performance, it is desired to further increase the mounting density. A similar problem occurs in not only a camera system of a lens-interchangeable type but also an optical device such as a camera system of a fixed lens type.

Japanese Patent Application Laid-Open No. 2024-77627 discloses a circuit module which includes a first circuit board including a first main surface and a second main surface and a second circuit board including a third main surface and a fourth main surface extending in a direction intersecting with the first main surface and in which the first circuit board and the second circuit board are soldered to each other.

In a circuit module applied to an electronic device such as an optical device, the demand for higher mounting density of a large number of electronic parts has been increasing, and there is a room for improvement.

### SUMMARY

The present disclosure provides a technique advantageous for realizing high-density mounting of a large number of electronic parts.

According to a first aspect of the present disclosure, a circuit module includes a first wiring board including a first main surface and a second main surface provided on an opposite side to the first main surface, and a second wiring board including a third main surface intersecting with a direction along the first main surface. The first main surface and the second main surface of the first wiring board are soldered to the third main surface of the second wiring board. The third main surface of the second wiring board includes an overlapping portion overlapping with the first wiring board in a first direction orthogonal to the third main surface, a first portion extending from the overlapping portion on one side in a second direction orthogonal to the first direction, and a second portion extending from the overlapping portion on another side in the second direction. W2<W1 is satisfied where W1 represents a length of the first wiring board in a third direction orthogonal to the first direction and the second direction, and W2 represents a length of the second wiring board in the third direction. L1<L2 is satisfied where L1 represents a length of the first portion in the second direction, and L2 represents a length of the second portion in the second direction. The circuit module further includes a plurality of electronic parts mounted on the second portion.

According to a second aspect of the present disclosure, a circuit module includes a first wiring board, a second wiring board, and a plurality of electronic parts. The first wiring board includes a first main surface, a second main surface provided on an opposite side to the first main surface, and an end surface interconnecting the first main surface and the second main surface. The second wiring board includes a third main surface intersecting with a direction along the first main surface. The plurality of electronic parts are mounted on the third main surface. The end surface includes a non-curved surface portion and a first curved surface portion connected to the non-curved surface portion. The first main surface and the second main surface of the first wiring board are soldered to the third main surface of the second wiring board in a state in which the non-curved surface portion is opposed to the third main surface of the second wiring board.

Features of the present disclosure will become apparent from the following description of embodiments with reference to the attached drawings. The following description of embodiments is described by way of example.

### BRIEF DESCRIPTION OF THE DRAWINGS

FIG. 1 is an explanatory diagram of an optical device according to a first embodiment.

FIG. 2A is a perspective view of a circuit module according to the first embodiment.

FIG. 2B is a side view of the circuit module according to the first embodiment.

FIG. 3 is a top view of the circuit module according to the first embodiment.

FIG. 4A is a front view of the circuit module according to the first embodiment.

FIG. 4B is an enlarged front view of a portion of the circuit module according to the first embodiment.

FIG. 5 is an enlarged perspective view of a portion of the circuit module according to the first embodiment.

FIG. 6 is a section view of a portion of the circuit module according to the first embodiment.

FIG. 7 is a section view of a portion of a circuit module according to a second embodiment.

FIG. 8A is a schematic perspective view of a circuit module according to a first modification example.

FIG. 8B is a schematic perspective view of the circuit module according to the first modification example.

FIG. 8C is a schematic perspective view of a circuit module according to a second modification example.

FIG. 8D is a schematic perspective view of the circuit module according to the second modification example.

FIG. 8E is a schematic perspective view of a circuit module according to a third modification example.

FIG. 8F is a schematic perspective view of the circuit module according to the third modification example.

### DESCRIPTION OF THE EMBODIMENTS

Embodiments of the present disclosure will be described in detail below with reference to drawings. The embodiments shown below are merely examples, and for example, details of the configuration thereof can be appropriately modified by one skilled in the art for implementation within the gist of the present disclosure.

To be noted, in the description of the embodiments below, it is assumed that elements denoted by the same reference signs have substantially the same function unless described otherwise. In the drawings, in the case where a plurality of the same elements are provided, addition of the reference signs and description thereof may be omitted. In addition, since the drawings are schematically expressed in some cases for the convenience of illustration and description, the shapes, sizes, arrangements, and the like of the elements illustrated in the drawings do not necessarily strictly match those of the elements illustrated in other drawings and elements in the real world.

In addition, in the description of the embodiments below, the directions are indicated in an XYZ coordinate system that is an orthogonal coordinate system. The X axis, the Y axis, and the Z axis are orthogonal to each other. In addition, the direction of the X axis, the direction of the Y axis, and the direction of the Z axis will be respectively referred to as an X direction, a Y direction, and a Z direction.

In addition, for example, the X direction includes two opposite directions along the X axis (+X direction and −X direction). The +X direction indicates one of the two directions, and the −X direction indicates the other of the two directions, that is, a direction opposite to the +X direction. The same applies to the Y axis and the Z axis other than the X axis.

In addition, a plane including the X axis and the Y axis will be referred to as an X-Y plane, a plane including the X axis and the Z axis will be referred to as an X-Z plane, and a plane including the Y axis and the Z axis will be referred to as a Y-Z plane.

### First Embodiment

### Optical Device

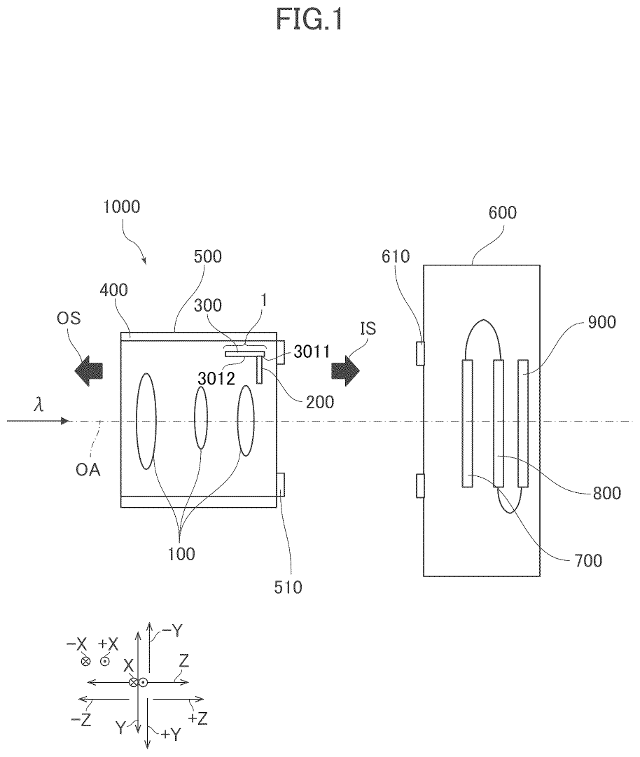

FIG. 1 is an explanatory diagram of an optical device 500 according to the first embodiment. FIG. 1 illustrates a camera 1000 including the optical device 500. The camera 1000 can be also referred to as a camera system. The camera 1000 includes a camera body 600. The optical device 500 is detachably attached to the camera body 600. The optical device 500 is, for example, an interchangeable lens (an interchangeable lens unit) in a camera of a lens-interchangeable type, but may be a lens unit in a camera of a fixed lens type.

The camera body 600 includes an image pickup device 700 that is an image sensor such as a complementary metal-oxide semiconductor (CMOS) image sensor or a charge-coupled device (CCD) image sensor. The camera body 600 can include a processing device 800 (image processing device) that performs image processing on an image signal output from the image pickup device 700. The camera body 600 can include a display device 900 that displays an image processed by the processing device 800. The display device 900 is a liquid crystal display or an organic electroluminescence display. The display device 900 may be an electronic view finder.

The optical device 500 includes a lens optical system 100, a circuit module 1, and a lens barrel 400. The lens optical system 100 can include a plurality of lenses. The circuit module 1 includes a main circuit board 200 and a sub circuit board 300. The main circuit board 200 is an example of a first circuit board. The sub circuit board 300 is an example of a second circuit board. The main circuit board 200 and the sub circuit board 300 are soldered to each other.

The circuit module 1 and the lens optical system 100 are disposed inside the lens barrel 400, and the circuit module 1 is fixed to the lens barrel 400. At least one lens in the lens optical system 100 can be fixed to the lens barrel 400, but at least one lens of the lens optical system 100 can move in the lens barrel 400 by being driven by an unillustrated ultrasonic motor (USM) that is an example of a motor.

The plurality of lenses included in the lens optical system 100 are arranged along an optical axis OA. Light λ from an object (imaging subject) is incident on the lens optical system 100. An object side OS and an image side IS are defined with respect to the lens optical system 100. The object (imaging subject) is positioned on the object side OS of the lens optical system 100, and the image pickup device 700 of the camera body 600 is positioned on the image side IS of the lens optical system 100. The sub circuit board 300 is disposed on the side opposite to the optical axis OA side of the main circuit board 200 so as not to block the light λ. That is, the sub circuit board 300 is disposed on the inner peripheral side of the lens barrel 400 of the main circuit board 200.

The optical device 500 includes a coupling mechanism 510, and the camera body 600 includes a coupling mechanism 610. The coupling mechanisms 510 and 610 are each a mount portion. The coupling mechanism 510 of the optical device 500 couples to the coupling mechanism 610 of the camera body 600, and the optical device 500 and the camera body 600 are thus mechanically and electrically connected to each other. As a result of this, the image pickup device 700 captures an image focused by the optical device 500. The coupling mechanisms 510 and 610 are omitted in a camera of a fixed lens type.

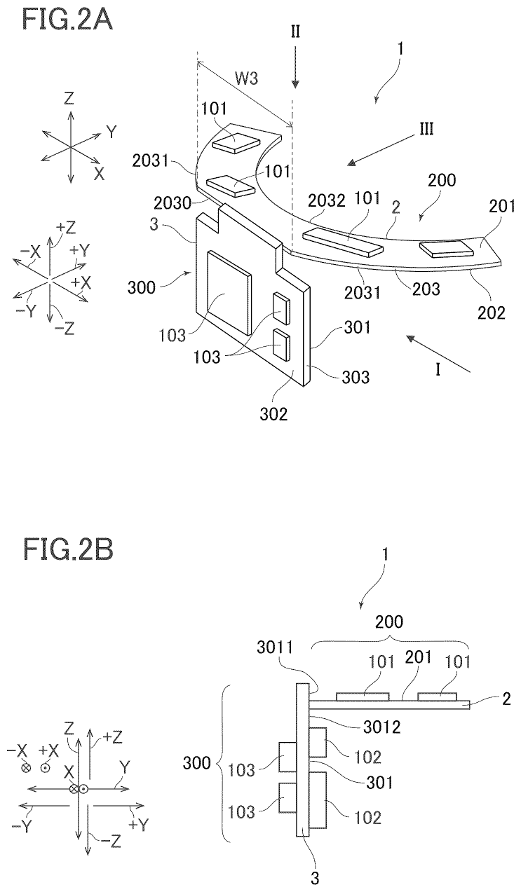

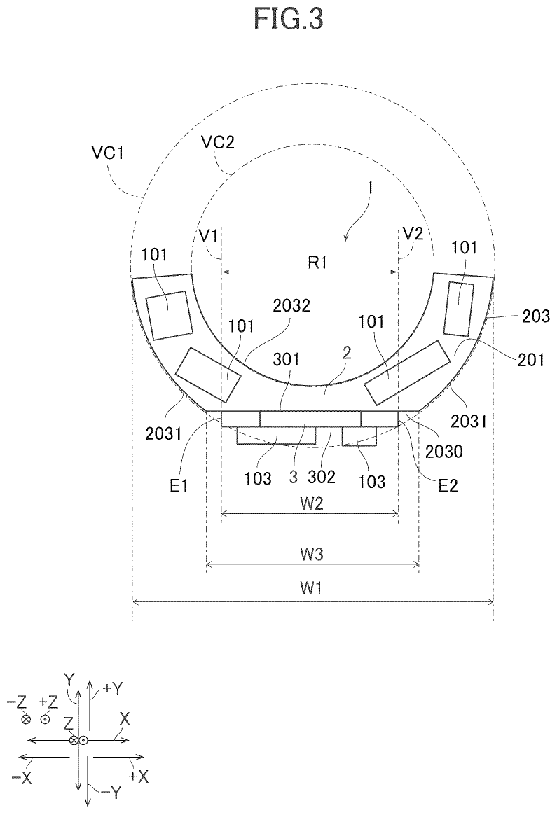

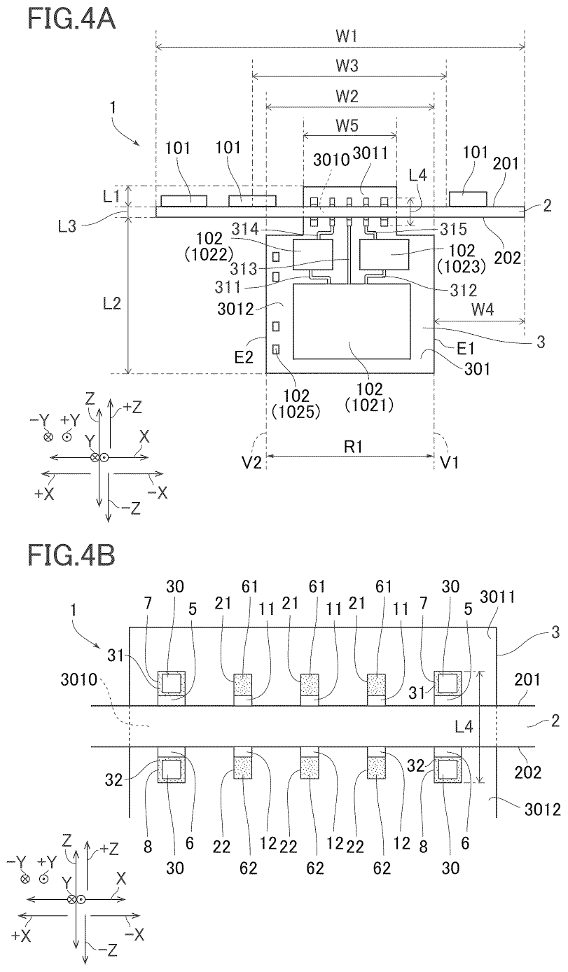

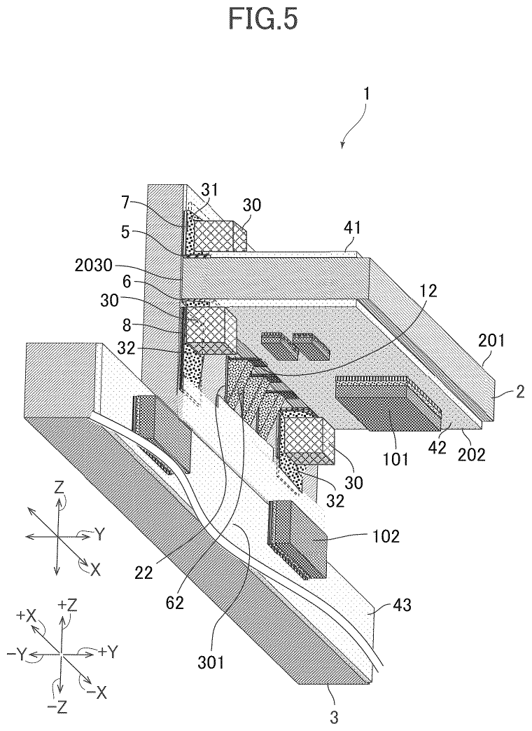

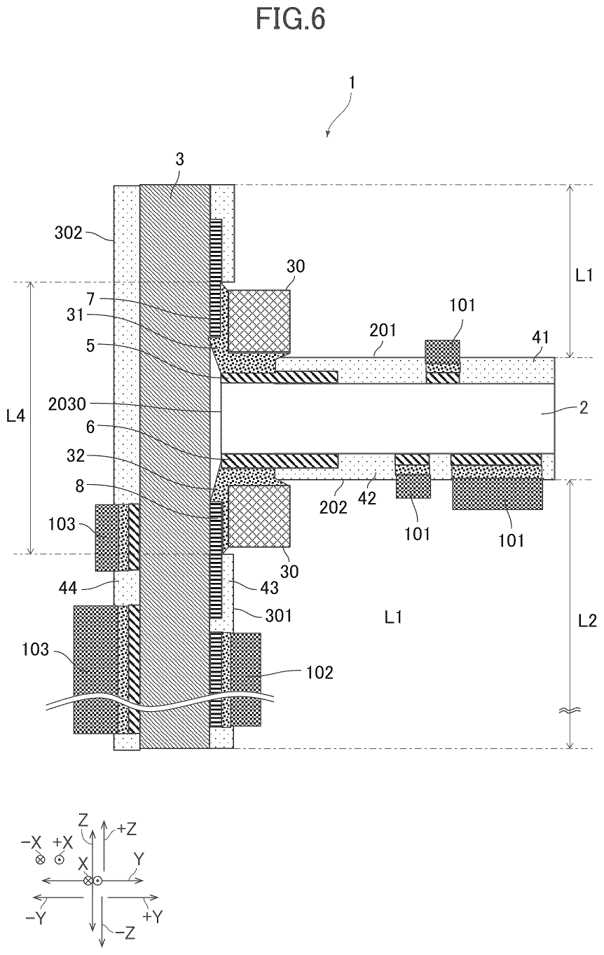

FIG. 2A is a perspective view of the circuit module 1 according to the first embodiment. FIG. 2B is a side view of the circuit module 1 as viewed in an arrow I direction of FIG. 2A. FIG. 3 is a top view of the circuit module 1 as viewed in an arrow II direction of FIG. 2A. FIG. 4A is a front view of the circuit module 1 as viewed in the arrow III direction of FIG. 2A. FIG. 4B is an enlarged front view of a portion of the circuit module 1 illustrated in FIG. 4A. FIG. 5 is an enlarged perspective view of a portion of the circuit module 1 according to the first embodiment. FIG. 6 is a section view of a portion of the circuit module 1 according to the first embodiment.

The circuit module 1 is a three-dimensional mounting structure. The main circuit board 200 includes a main wiring board 2, and a plurality of electronic parts 101 mounted on the main wiring board 2. The sub circuit board 300 includes a sub wiring board 3 and a plurality of electronic parts 102 and a plurality of electronic parts 103 mounted on the sub wiring board 3. The main wiring board 2 is an example of a first wiring board. The sub wiring board 3 is an example of a second wiring board. The electronic parts 101 are an example of third electronic parts.

The main wiring board 2 includes a main surface 201, a main surface 202 provided on the opposite side to the main surface 201, and an end surface 203 interconnecting the main surfaces 201 and 202. The main surface 202 is parallel to the main surface 201. The sub wiring board 3 includes a main surface 301, a main surface 302 on the opposite side to the main surface 301, and an end surface 303 interconnecting the main surface 301 and 302. The main surface 302 is parallel to the main surface 301. The main surface 201 is an example of a first main surface. The main surface 202 is an example of a second main surface. The main surface 301 is an example of a third main surface. The main surface 302 is an example of a fourth main surface.

The main wiring board 2 and the sub wiring board 3 each can be, for example, a rigid board. In addition, the main wiring board 2 and the sub wiring board 3 each can be a printed wiring board.

The main wiring board 2 includes an insulating substrate and at least two conductive layers. Two conductive layers in the at least two conductive layers are outer layers respectively disposed on the two main surfaces of the insulating substrate. A solder resist is disposed on each of the two outer layers.

The sub wiring board 3 includes an insulating substrate and at least one conductive layer. One conductive layer in the at least one conductive layer is an outer layer disposed on the insulating substrate. In the present embodiment, the sub wiring board 3 includes at least two conductive layers. Two conductive layers in the at least two conductive layers are outer layers respectively disposed on the two main surfaces of the insulating substrate. A solder resist is disposed on each of the two outer layers.

Each conductive layer of the main wiring board 2 and the sub wiring board 3 includes wiring constituted by a conductive member such as copper. Examples of the insulating substrate of each of the main wiring board 2 and the sub wiring board 3 include a glass epoxy substrate, a resin substrate other than the glass epoxy substrate, and a ceramic substrate.

At least one of the main surfaces 201 and 202 of the main wiring board 2 is a mounting surface on which mounted parts can be mounted, and in the first embodiment, the main surfaces 201 and 202 are each a mounting surface. The plurality of electronic parts 101 are surface-mounted on the main surfaces 201 and 202.

At least the main surface 301 among the main surfaces 301 and 302 of the sub wiring board 3 is a mounting surface on which mounted parts can be mounted, and in the first embodiment, the main surfaces 301 and 302 are each a mounting surface. The plurality of electronic parts 102 are surface-mounted on the main surface 301, and the plurality of electronic parts 103 are surface-mounted on the main surface 302.

The plurality of electronic parts 101 may be each an integrated circuit part (semiconductor part) that is an active part, or a passive part. The plurality of electronic parts 102 may be each an integrated circuit part (semiconductor part) that is an active part, or a passive part. The plurality of electronic parts 103 may be each an integrated circuit part (semiconductor part) that is an active part, or a passive part.

The integrated circuit part can be a part including a control circuit for auto-focusing, a power source circuit for a sensor, a drive circuit for driving, or the like. The passive part can be, for example, a surface-mountable chip part such as a chip resistor, a chip capacitor, or a chip inductor, or a coil.

In the first embodiment, the X direction, the Y direction, and the Z direction are based on the main surface 301 of the sub wiring board 3. Here, the main surfaces 301 and 302 of the sub wiring board 3 may each include fine protrusions and recesses, and the main surfaces 201 and 202 of the main wiring board 2 may each include fine protrusions and recesses. The directions based on the main surface 301 of the sub wiring board 3 are based on a flat surface having the largest area in the main surface 301. The same applies to cases based on the main surfaces 302, 201, and 202.

The main surface 301 of the sub wiring board 3 includes a flat surface parallel to the X-Z plane. The direction orthogonal to the main surface 301 of the sub wiring board 3 is a Y direction. The main surface 301 faces in the +Y direction, and the main surface 302 faces in the −Y direction. The main wiring board 2 is disposed on the +Y direction side with respect to the sub wiring board 3.

The Y direction is also an out-of-plane direction of the main surface 301, and a thickness direction of the sub wiring board 3. The Z direction and the X direction are each also a direction along the main surface 301, that is, an in-plane direction of the main surface 301. Here, the Y direction is an example of a first direction, the Z direction orthogonal to the Y direction is an example of a second direction, and the X direction orthogonal to the Y direction and the Z direction is an example of a third direction.

The main surface 301 of the sub wiring board 3 is a surface extending in a direction intersecting with the main surface 201 of the main wiring board 2. In other words, the main surface 201 of the main wiring board 2 is a surface extending in a direction intersecting with the main surface 301 of the sub wiring board 3. The main surface 302 of the sub wiring board 3 faces the inner peripheral surface of the lens barrel 400.

To be noted, in the first embodiment, the angle between the Z axis and the optical axis OA is, for example, 0°, but may be larger than 0°, and can be 30° or less. In addition, although the main surface 201 of the main wiring board 2 can be orthogonal to the main surface 301 of the sub wiring board 3, the main surface 201 of the main wiring board 2 may be slightly inclined with respect to the main surface 301 of the sub wiring board 3. That is, the angle between the main surface 201 and the main surface 301 can be 90°, but may be in a range of 90°±30°.

In the first embodiment, a case where the angle between the Z axis and the optical axis OA is 0°, that is, the optical axis OA is parallel to the Z axis and the angle between the main surface 201 and the main surface 301 is 90°, that is, the direction orthogonal to the main surface 201 is the Z direction, will be described as an example. The +Z direction is the incident direction (traveling direction) of the light λ. The flat surface of each of the main surfaces 201 and 202 of the main wiring board 2 is parallel to the X-Y plane.

The main wiring board 2 can have a shape following the inner peripheral surface of the lens barrel 400 so as not to block the light λ from the viewpoint of securing a large mounting area, and has a shape in which a portion of an arcuate shape is cut out as viewed in the Z direction orthogonal to the main surface 201, or a shape in which a portion of an annular shape is cut out as viewed in the Z direction orthogonal to the main surface 201. In the present embodiment, the main wiring board 2 has a shape in which a portion of an arcuate shape is cut out as viewed in the Z direction orthogonal to the main surface 201.

In addition, the sub wiring board 3 is a wiring board having a shape in which a portion of a rectangular shape is cut out as viewed in the Y direction orthogonal to the main surface 301. The sub wiring board 3 includes a region wide in the X direction, and a protruding region that is narrow in the X direction.

Here, viewing in the Z direction includes seeing through in the Z direction. In addition, the expression “in the Z direction” can include “as viewed in the Z direction”. The same applies to the X direction and the Y direction.

The end surface 203 of the main wiring board 2 includes a non-curved surface portion 2030, a pair of curved surface portions 2031 connected to the non-curved surface portion 2030, and a curved surface portion 2032 provided on the opposite side to the non-curved surface portion 2030 in the Y direction. The non-curved surface portion 2030 and the pair of curved surface portions 2031 are positioned at the outer periphery of the main wiring board 2, and the curved surface portion 2032 is positioned at the inner periphery of the main wiring board 2. The pair of curved surface portions 2031 are each an example of a first curved surface portion, and the curved surface portion 2032 is an example of a second curved surface portion. The non-curved surface portion 2030 is disposed between the pair of curved surface portions 2031. To be noted, one of the pair of curved surface portions 2031 may be omitted.

In the first embodiment, the non-curved surface portion 2030 is a flat surface portion. The X direction serves as the longitudinal direction of the non-curved surface portion 2030. One of the pair of curved surface portions 2031 is connected to one of two ends of the non-curved surface portion 2030 in the X direction, and the other of the pair of curved surface portions 2031 is connected to the other of the two ends of the non-curved surface portion 2030 in the X direction.

Here, as illustrated in FIG. 3, two virtual circles VC1 and VC2 parallel to the X-Y plane and having different radiuses are defined. The virtual circle VC2 having a small radius is positioned on the inside of the virtual circle VC1 having a large radius. The two virtual circles VC1 and VC2 can be concentric circles. In addition, the optical axis OA of FIG. 1 passes inside the two virtual circles VC1 and VC2.

The pair of curved surface portions 2031 extend the virtual circle VC1 having a large radius among the two virtual circles VC1 and VC2, and the curved surface portion 2032 extend along the virtual circle VC2 having a small radius among the two virtual circles VC1 and VC2. As described above, in the first embodiment, the curvature radius of the curved surface portion 2032 is smaller than the curvature radius of the pair of curved surface portions 2031 from the viewpoint of securing the area of the main surfaces 201 and 202.

In the first embodiment, at least a portion of the non-curved surface portion 2030 opposes a portion of the main surface 301 of the sub wiring board 3 in the Y direction directly or with a member therebetween. Further, in a state in which the non-curved surface portion 2030 is opposed to the main surface 301 of the sub wiring board 3, the main surfaces 201 and 202 of the main wiring board 2 are soldered to the main surface 301 of the sub wiring board 3.

As described above, as a result of the main wiring board 2 and the sub wiring board 3 being soldered to each other in a state in which a portion of the end surface 203 of the main wiring board 2 is opposed to the main surface 301 of the sub wiring board 3, a region in which the plurality of electronic parts 101 can be mounted on the main surfaces 201 and 202 of the main wiring board 2 can be secured more sufficiently than in a case where a portion of the end surface of the sub wiring board is opposed to the mounting surface of the main wiring board. Further, the circuit module 1 can be miniaturized while securing a region in which a large number of electronic parts 101 to 103 can be mounted in the circuit module 1, and thus the circuit module 1 can be disposed in a small space inside the lens barrel 400 in a state of not blocking the light λ. According to the configuration described above, further high-density mounting of the large number of electronic parts 101, 102, and 103 in the circuit module 1 can be realized.

In addition, in the first embodiment, the main surface 301 of the sub wiring board 3 includes an overlapping portion 3010 overlapping with the main wiring board 2 in the Y direction orthogonal to the main surface 301, an extending portion 3011 extending from the overlapping portion 3010 on one side (+Z side) in the Z direction orthogonal to the Y direction, and an extending portion 3012 extending from the overlapping portion 3010 on the other side (-Z side) in the Z direction. The extending portion 3011 is an example of a first portion, and the extending portion 3012 is an example of a second portion.

Here, the electric and mechanical connection relationship between the main wiring board 2 and the sub wiring board 3 will be described in detail. The main wiring board 2 includes a solder resist 41 and a plurality of pads constituting the main surface 201, and a solder resist 42 and a plurality of pads constituting the main surface 202. The sub wiring board 3 includes a solder resist 43 and a plurality of pads constituting the main surface 301, and a solder resist 44 and a plurality of pads constituting the main surface 302. The plurality of pads are each formed from a conductor such as copper, and the solder resists 41 to 44 are each a film formed from a solder resist material.

The plurality of pads formed on the main wiring board 2 and the plurality of pads formed on the sub wiring board 3 each may be a solder mask defined (SMD) pad, or a non-solder mask defined (NSMD) pad. Considering the bondability with solder, each pad can be an NSMD pad.

The plurality of pads on the main surface 201 of the main wiring board 2 include two or more pads used for bonding with the electronic parts 101, and two or more pads 11 used for bonding with the main surface 301 of the sub wiring board 3.

The plurality of pads on the main surface 202 of the main wiring board 2 include two or more pads used for bonding with the electronic parts 101, and two or more pads 12 used for bonding with the main surface 301 of the sub wiring board 3.

The two or more pads 11 and the two or more pads 12 are arranged at a distal end portion of the main wiring board 2 in the-Y direction.

The plurality of pads on the main surface 301 of the sub wiring board 3 include two or more pads used for bonding with the electronic parts 102, two or more pads 21 used for bonding with the main surface 201 of the main wiring board 2, and two or more pads 22 used for bonding with the main surface 202 of the main wiring board 2.

The plurality of pads on the main surface 302 of the sub wiring board 3 include two or more pads used for bonding with the electronic parts 103.

In a state in which the non-curved surface portion 2030 that is a portion of the end surface 203 of the main wiring board 2 is opposed to the main surface 301 of the sub wiring board 3, the two or more pads 11 on the main surface 201 of the main wiring board 2 and the two or more pads 21 on the main surface 301 of the sub wiring board 3 are respectively bonded to each other via solder 61, and the two or more pads 12 on the main surface 202 of the main wiring board 2 and the two or more pads 22 on the main surface 301 of the sub wiring board 3 are respectively bonded to each other via solder 62.

In the first embodiment, the circuit module 1 is provided with a plurality of assisting members 30 for reinforcing the bonding between the main wiring board 2 and the sub wiring board 3. The plurality of assisting members 30 are each a member for assisting the mechanical connection between the main wiring board 2 and the sub wiring board 3. The plurality of assisting members 30 each can be a member having conductivity and rigidity, and are each, for example, a metal member having a rectangular parallelepiped shape. The plurality of assisting members 30 are arranged in a split manner on the respective sides of the main wiring board 2 in the Z direction that is the thickness direction of the main wiring board 2 such that the main wiring board 2 is interposed therebetween as illustrated in FIGS. 5 and 6. To be noted, FIG. 5 illustrates a perspective view of a region including a bonding portion between the main wiring board 2 and the sub wiring board 3 in the circuit module 1. FIG. 6 illustrates a section view of the region including the bonding portion between the main wiring board 2 and the sub wiring board 3 in the circuit module 1. Specifically, FIG. 6 is a diagram illustrating a cross-section of the circuit module 1 taken along a plane parallel to the Y-Z plane and intersecting with the assisting member 30 as viewed in the-X direction.

The plurality of pads on the main surface 201 of the main wiring board 2 include pads 5 used for bonding with the assisting members 30 disposed on the main surface 201 side. The plurality of pads on the main surface 202 of the main wiring board 2 include pads 6 used for bonding with the assisting members 30 disposed on the main surface 202 side.

The plurality of pads on the main surface 301 of the sub wiring board 3 include pads 7 used for bonding with the assisting members 30 disposed on the main surface 201 side, and pads 8 used for bonding with the assisting members 30 disposed on the main surface 202 side.

The assisting members 30 disposed on the main surface 201 side are bonded to the pads 5 and 7 via solder 31. The assisting members 30 disposed on the main surface 202 side are bonded to the pads 6 and 8 via solder 32. As a result of this, the bonding between the main wiring board 2 and the sub wiring board 3 is reinforced.

In addition, as a result of providing the assisting members 30, the inclination amount by which the main wiring board 2 is inclined with respect to a direction orthogonal to the main surface 301 of the sub wiring board 3 by a shake during transport or a hot air when solder is melted in a soldering step can be reduced. That is, the assisting members 30 are also used for assisting the main wiring board 2 to stand up by itself with respect to the sub wiring board 3 in a manufacturing process of the circuit module 1. As a result of this, the fillet shapes and thickness of the solders 31, 32, 61, and 62 bonding the main wiring board 2 and the sub wiring board 3 to each other are less likely to vary. Therefore, the uniformity of the fillet shapes and thickness of the solders 31, 32, 61, and 62 is improved, and the bonding strength of the solders 31, 32, 61, and 62 is improved.

To be noted, although a case where the assisting member 30 is a conductive member has been described as an example, the configuration is not limited to this. The assisting member 30 may be a member such as an adhesive or resin fixing the main wiring board 2 to the sub wiring board 3. In this case, the pads 5, 6, 7, and 8 and the solders 31 and 32 can be omitted.

In the case where the length of the main wiring board 2 in the X direction orthogonal to the Y direction and the Z direction is denoted by W1 and the length of the sub wiring board 3 in the X direction is denoted by W2, W2<W1 is satisfied. The length W1 can be also the width of the main wiring board 2, and the length W2 can be also the width of the sub wiring board 3. That is, the width of the main wiring board 2 is larger than the width of the sub wiring board 3.

In the first embodiment, the main wiring board 2 has a shape in which a portion of an arcuate shape is cut out as viewed in the Z direction orthogonal to the main surface 201. In the case where the length of the non-curved surface portion 2030 in the X direction that is a straight line as viewed in the Z direction is denoted by W3, W2≤W3<W1 is satisfied.

Here, the wiring of the sub wiring board 3 is connected to each of the plurality of electronic parts 102 disposed on the main surface 301 of the sub wiring board 3. In the first embodiment, the wiring of the sub wiring board 3 can be as short as possible from the viewpoint of impedance or the like. From a viewpoint like this, the plurality of electronic parts 102 can be arranged in an integrated manner on the main surface 301 without being split by the main wiring board 2.

In the first embodiment, in the case where the length of the extending portion 3011 in the Z direction is denoted by L1 and the length of the extending portion 3012 in the Z direction is denoted by L2, 0<L1<L2 is satisfied. That is, the area of the extending portion 3012 is larger than the area of the extending portion 3011. As a result of this, the plurality of electronic parts 102 can be mounted on the extending portion 3012 in an integrated manner. Therefore, the wiring can be shortened, and the plurality of electronic parts 102 can be mounted on the sub wiring board 3 with high density while securing an electric reliability of the wiring connected to the plurality of electronic parts 102. As described above, according to the first embodiment, further high-density mounting of the large number of electronic parts 101, 102, and 103 in the circuit module 1 can be realized.

In addition, as a result of satisfying 0<L1<L2, the plurality of electronic parts 102 mounted on the sub wiring board 3 do not need to be arranged such that the main wiring board 2 is interposed therebetween. In the first embodiment, the plurality of electronic parts 102 are mounted on the extending portion 3012. As a result of this, relatively large electronic parts, that is, the plurality of electronic parts 102 among the plurality of electronic parts included in the circuit module 1 can be disposed on the extending portion 3012 of the main surface 301 of the sub wiring board 3. Further, the wiring interconnecting the plurality of electronic parts 102 does not need to be provided to extend around the main wiring board 2, does not need to be provided in an inner layer of the sub wiring board 3, and can be disposed in a conductive layer positioned outermost in the sub wiring board 3. Therefore, the wiring length of the wiring interconnecting the plurality of electronic parts 102 can be shortened, and thus disconnection can be reduced.

In addition, an integrated circuit part that is a relatively large electronic part is not mounted on the extending portion 3011. To be noted, passive parts that are relatively small electronic parts may be mounted on the extending portion 3011.

The length L2 of the extending portion 3012 in the Z direction can be equal to or more than 9 times of the length L1 of the extending portion 3011 in the Z direction. As a result of this, the area of the extending portion 3012 of the sub wiring board 3 can be made as large as possible while securing the reliability of the bonding between the main wiring board 2 and the sub wiring board 3, and thus more electronic parts 102 can be mounted on the extending portion 3012 highly densely.

The plurality of electronic parts 102 mounted on the extending portion 3012 of the main surface 301 includes one or more integrated circuit parts and one or more passive parts. The one or more integrated circuit parts are, for example, integrated circuit parts 1021, 1022, and 1023. The integrated circuit parts 1021, 1022, and 1023 are each a semiconductor part. The integrated circuit part 1021 is an example of a first electronic part. The integrated circuit parts 1022 and 1023 are each an example of a second electronic part. The one or more passive parts are, for example, a chip part 1025. The integrated circuit parts 1021, 1022, and 1023 are each larger in size than the passive part, that is, the chip part 1025. The integrated circuit part 1021 is larger in size than each of the plurality of electronic parts 101. That is, the integrated circuit parts large in size can be mounted on the sub wiring board 3. To be noted, the second electronic part electrically connected to the integrated circuit part 1021 via the wiring of the sub wiring board 3 may be a passive part, for example, the chip part 1025.

At least one of the plurality of electronic parts 102, that is, each of the integrated circuit parts 1022 and 1023 in the first embodiment, is a part including a drive circuit that controls the driving of the lens by an unillustrated USM. The integrated circuit part 1021 integrally controls the integrated circuit parts 1022 and 1023. The integrated circuit parts 1021 and 1022 are electrically interconnected by wiring 311 of the sub wiring board 3. In addition, the integrated circuit parts 1021 and 1023 are electrically interconnected by wiring 312 of the sub wiring board 3. To be noted, the integrated circuit parts 1021, 1022, and 1023 are electrically connected to the main wiring board 2 respectively via wirings 313, 314, and 315 of the sub wiring board 3.

For the circuit module 1, since integrated circuit parts such as the integrated circuit parts 1022 and 1023 including drive circuits are disposed on the sub wiring board 3, the number of parts disposed on the main wiring board 2 can be reduced, and thus the area of the main wiring board 2 can be reduced. As one method for reducing the area of the main wiring board 2, a wider space can be secured for the lens optical system 100 by increasing the inner diameter of the main wiring board 2 having an arcuate shape. As a result of this, the outer diameter of each lens of the lens optical system 100 can be increased, the length of the lens optical system 100 in the direction of the optical axis OA can be reduced, and as a result, the optical device 500 can be miniaturized and a wider view angle can be obtained as an optical function.

In the first embodiment, the integrated circuit parts 1021, 1022, and 1023 are mounted on the extending portion 3012 of the main surface 301. That is, the integrated circuit parts 1021, 1022, and 1023 that are relatively large in size can be mounted on the extending portion 3012. Further, the wirings 311 and 312 of the sub wiring board 3 are disposed at positions not overlapping with the main wiring board 2 in the Y direction orthogonal to the main surface 301 of the sub wiring board 3. As a result of this, the wirings 311 and 312 can be shortened. In addition, the wirings 311 and 312 are provided without being extending around the main wiring board 2. Therefore, further high-density mounting of the large number of electronic parts 101, 102, and 103 in the circuit module 1 can be realized while securing the electric reliability of the wirings 311 and 312.

In addition, in the first embodiment, the main wiring board 2 has a shape in which a portion of an arcuate shape is cut out as viewed in the Z direction orthogonal to the main surface 201. As a result of this, the non-curved surface portion 2030 of the end surface 203 of the main wiring board 2 can be made closer to the main surface 301 of the sub wiring board 3, and the main wiring board 2 can be easily bonded to the sub wiring board 3 with solder. In addition, increase in the size of the optical device 500 toward the outside in the radial direction of the lens barrel 400 can be suppressed without restricting the outer diameter of the lens on the inside of the main wiring board 2.

Here, as illustrated in FIG. 4A, two virtual planes V1 and V2 are defined. The virtual plane V1 is an example of a first virtual plane, and the virtual plane V2 is an example of a second virtual plane. The virtual plane V1 is a virtual plane extending in the Y direction and the Z direction and parallel to the Y-Z plane. The virtual plane V2 is a virtual plane parallel to the virtual plane V1 and separated from the virtual plane V1 by the length W2 in the X direction. The virtual plane V1 is in contact with one end E1 among two ends E1 and E2 of the sub wiring board 3 in the X direction. The virtual plane V2 is in contact with the other end E2 among the two ends E1 and E2 of the sub wiring board 3 in the X direction. The end E1 is an example of a first end, and the end E2 is an example of a second end.

In the first embodiment, at least a portion of at least one electronic part 101 among the plurality of electronic parts 101 is positioned outside a region R1 between the virtual planes V1 and V2. In the example of FIGS. 3 and 4A, the entirety of each of two electronic parts 101 among four electronic parts 101 is positioned outside the region R1, and a portion of each of two electronic parts 101 among the four electronic parts 101 is positioned outside the region R1. That is, since the main wiring board 2 has an arcuate shape with a cutout, the relatively large electronic parts 101 are disposed outside the region R1 partially or entirely.

In addition, as illustrated in FIG. 4A, a length W4 (=W1−W2) in the X direction of a portion of the main wiring board 2 outside the region R1 can be equal to or larger than the length of the shortest side of the smallest one of the plurality of electronic parts 101 mounted on the main wiring board 2. In other words, in the case where the thickness of the main wiring board 2 is denoted by L3, W1−W2≥L3 is satisfied. By employing such a size, an area in which the plurality of electronic parts 101 are mounted on the main wiring board 2 can be secured.

In addition, the main wiring board 2 and a portion of the sub wiring board 3 on the extending portion 3012 side are fixed to each other via parts constituting lenses of the optical device 500, an unillustrated rubber bush between the inner casing and the outer casing, and the like. In contrast, a portion of the sub wiring board 3 on the extending portion 3011 side cannot be fixed by the rubber bush or the like, and is in a free state.

In the first embodiment, in the case where the distance between the end of the solder 31 protruding the most toward one side (+Z side) in the Z direction from the main surface 201 among the plurality of solders 61 and the plurality of solders 31 and the end of the solder 32 protruding the most toward the other side (-Z side) in the Z direction from the main surface 202 among the plurality of solders 62 and the plurality of solders 32 is denoted by L4, L1≤L4 is satisfied. As a result of satisfying L1≤L4, the bonding strength of the solder bonding portion between the main wiring board 2 and the sub wiring board 3 increases, vibration on the extending portion 3011 side of the sub wiring board 3 at the time of impact such as a drop of the optical device 500 is suppressed, and the reliability of the bonding by the solder bonding portion is improved.

In addition, the length of the extending portion 3011 in the X direction will be denoted by W5. As illustrated in FIG. 1, the sub circuit board 300 is disposed on the outer peripheral side of the main circuit board 200. Therefore, in the first embodiment, from the viewpoint of disposing the circuit module 1 in a narrow space on the inside of the lens barrel 400, the length W5 of the extending portion 3011 is smaller than the length W3 of the non-curved surface portion 2030 (W5<W3).

In addition, as illustrated in FIG. 1, in a state in which the optical device 500 is attached to the camera body 600, the extending portion 3011 is closer to the camera body 600 than the extending portion 3012. That is, the optical device 500 includes the coupling mechanism 510 that is an example of a mount portion for attaching the optical device 500 to the camera body 600. Therefore, the extending portion 3011 is closer to the coupling mechanism 510 than the extending portion 3012. As a result of this, the amount of protrusion of the sub wiring board 3 (sub circuit board 300) toward the camera body 600 side can be reduced, and collision of the sub wiring board 3 with members therearound can be suppressed.

As described above, according to the first embodiment, a technique advantageous for realizing further high-density mounting of a large number of electronic parts can be provided.

### Second Embodiment

A second embodiment will be described. In the description below, it is assumed that elements denoted by the same reference signs as in the first embodiment have substantially the same configurations and functions as those described in the first embodiment unless described otherwise, and part different from the first embodiment will be mainly described.

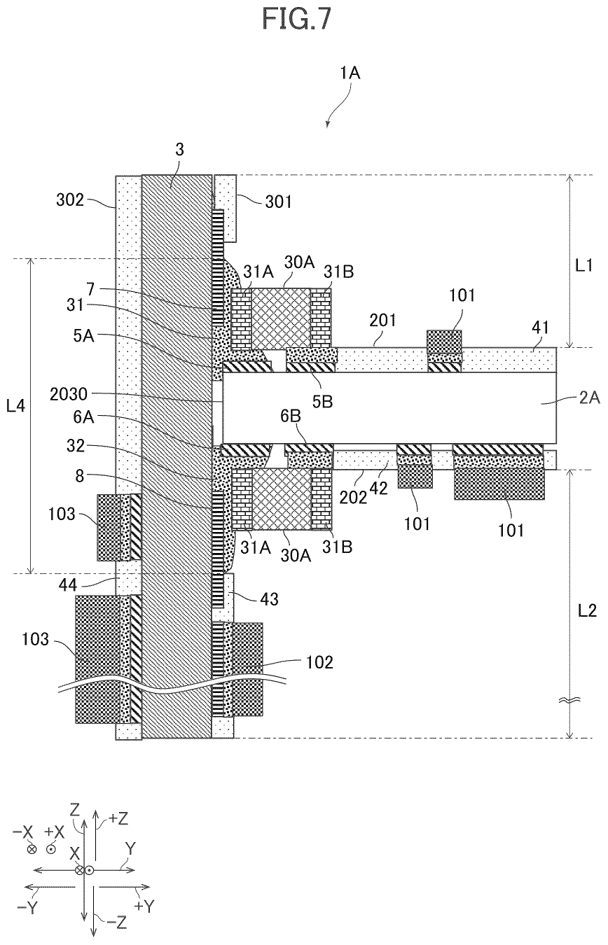

FIG. 7 is a section view of a portion of a circuit module 1A according to the second embodiment. The optical device of the second embodiment has a configuration in which the circuit module 1A is disposed on the inside of the lens barrel 400 instead of the circuit module 1 in the optical device 500 of the first embodiment illustrated in FIG. 1. Elements in the optical device of the second embodiment are substantially the same as in the optical device 500 of the first embodiment except for the circuit module 1A, and therefore description thereof will be omitted.

The circuit module 1A is a three-dimensional mounting structure. The circuit module 1A of the second embodiment includes a main wiring board 2A instead of the main wiring board 2, the sub wiring board 3, and a plurality of passive parts 30A serving as an example of assisting members instead of the plurality of assisting members 30. In the circuit module 1A, the elements other than the main wiring board 2A and the passive parts 30A are the same as in the circuit module 1. To be noted, FIG. 7 illustrates a section view of a region including a bonding portion between the main wiring board 2A and the sub wiring board 3 in the circuit module 1A. Specifically, FIG. 7 is a diagram illustrating a cross-section of the circuit module 1A taken along a plane parallel to the Y-Z plane and intersecting with the passive parts 30A as viewed in the-X direction.

Part of the configuration of the main wiring board 2A is different from the main wiring board 2. Specifically, the main wiring board 2A includes pads 5A and 5B instead of the pads 5, and pads 6A and 6B instead of the pads 6. The elements in the main wiring board 2A are substantially the same as in the main wiring board 2 except for the pads 5A, 5B, 6A, and 6B.

On the main surface 201 of the main wiring board 2A, the pads 5A are disposed at an interval from the pads 5B in the Y direction, and on the main surface 202 of the main wiring board 2A, the pads 6A are disposed at an interval from the pads 6B in the Y direction.

The passive part 30A is an electronic part such as a resistor, a capacitor, or an inductor. In the second embodiment, the passive part 30A is a chip part that can be surface-mounted. The passive part 30A includes two electrodes 31A and 31B. In the passive part 30A, the direction in which the two electrodes 31A and 31B are arranged is the longitudinal direction.

The electrodes 31A and 31B of the passive part 30A disposed on the main surface 201 side of the main wiring board 2A respectively oppose the pads 5A and 5B in the Z direction. The electrodes 31A and 31B of the passive part 30A disposed on the main surface 202 side of the main wiring board 2A respectively oppose the pads 6A and 6B in the Z direction. As a result of this, the passive part 30A is disposed such that the longitudinal direction of the passive part 30A is parallel to or approximately parallel to the Y direction orthogonal to the main surface 301 of the sub wiring board 3.

The electrode 31A of the passive part 30A disposed on the main surface 201 side of the main wiring board 2A opposes a pad 7 in the Y direction. The electrode 31A of the passive part 30A disposed on the main surface 202 side of the main wiring board 2A opposes a pad 8 in the Y direction.

The electrode 31A of the passive part 30A disposed on the main surface 201 side of the main wiring board 2A is electrically and mechanically connected to the pad 5A and the pad 7 by being bonded to the pad 5A and the pad 7 via the solder 31. The electrode 31A of the passive part 30A disposed on the main surface 202 side of the main wiring board 2A is electrically and mechanically connected to the pad 6A and the pad 8 by being bonded to the pad 6A and the pad 8 via the solder 32.

As the passive part 30A, one of an appropriate size is selected in accordance with the thickness and size of the main wiring board 2A, the space between the main wiring board 2A and the sub wiring board 3, and the like. The plurality of passive parts 30A can be disposed on the respective sides of the main wiring board 2A in consideration of the standability of the main wiring board 2A.

The passive part 30A can be a chip part including two electrodes 31A and 31B, and the main wiring board 2A and the sub wiring board 3 can be disposed such that the main wiring board 2A and the sub wiring board 3 are orthogonal to each other. As a result, the uniformity of the fillet shape of solder improves, and thus the bonding strength of the solder bonding portion improves. In addition, the noise can be reduced by providing the passive part 30A, and by electrically connecting one of the two electrodes 31A and 31B of the passive part 30A to the ground of the power source circuit, the stability of the electric operation in the circuit module 1A can be improved.

To be noted, although a case where the pads 5A are disposed at an interval in the Y direction from the pads 5B and the pads 6A are disposed at an interval in the Y direction from the pads 6B on the main wiring board 2A has been described in the second embodiment, the configuration is not limited to this. For example, the pads 5A may be disposed at an interval in the X direction from the pads 5B, and the pads 6A may be disposed at an interval in the X direction from the pads 6B. In this case, the passive parts 30A are disposed such that the longitudinal direction thereof is parallel or approximately parallel to the X direction.

As described above, according to the second embodiment, a technique advantageous for realizing further high-density mounting of a large number of electronic parts can be provided similarly to the first embodiment.

### Modification Example

A modification example of the first embodiment will be described. In the description below, it is assumed that elements denoted by the same reference signs as in the first embodiment have substantially the same configurations and functions as those described in the first embodiment unless described otherwise, and part different from the first embodiment will be mainly described.

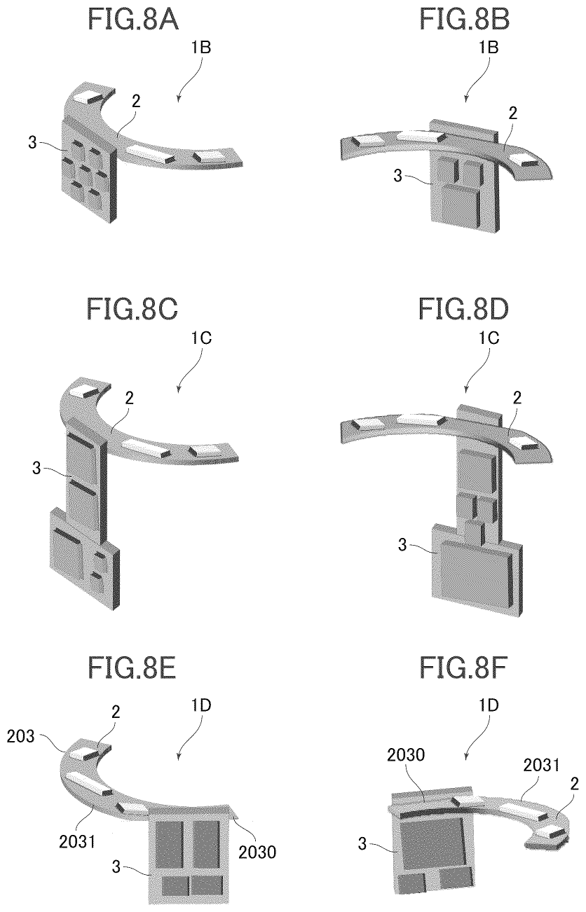

FIGS. 8A and 8B are each a schematic perspective view of a circuit module 1B according to a first modification example. FIGS. 8C and 8D are each a schematic perspective view of a circuit module 1C according to a second modification example. FIGS. 8E and 8F are each a schematic perspective view of a circuit module 1D according to a third modification example. In the circuit modules 1B to 1D, the size and arrangement of the electronic parts and the shape and size of the main wiring board 2 or the sub wiring board 3 are different from the first embodiment.

In the circuit module 1B, the shape of the sub wiring board 3 is rectangular in plan view. In the circuit module 1C, the sub wiring board 3 has a rectangular shape with a cutout in plan view, and includes a wide region and a narrow protruding region similarly to the first embodiment, but the length of the narrow protruding region in the longitudinal direction is larger than that of the sub wiring board 3 of the first embodiment. In the circuit module 1D, the shape of the main wiring board 2 is different from the first embodiment. That is, the end surface 203 of the main wiring board 2 includes the curved surface portion 2031 on only one side of the non-curved surface portion 2030 in the longitudinal direction.

In the circuit modules 1B to 1D of the first to third modification examples, for example, electronic parts (for example, integrated circuit parts) that are easily affected by a noise from the outside may be disposed on the main surface 301 of the sub wiring board 3. The electronic parts that are easily affected by the noise from the outside can be disposed to overlap with an inner layer of the sub wiring board 3 in which a ground pattern is disposed, in the thickness direction of the sub wiring board 3.

The shape of the sub wiring board 3, the bonding position between the main wiring board 2 and the sub wiring board 3, and the size, number, and arrangement of the electronic parts are appropriately set in accordance with the function of the optical device 500, the arrangement of the lens optical system 100 and the like, the clearance between the lens barrel 400 and parts, and the like.

To be noted, the modifications like the first to third modification examples described above are also applicable to the circuit module 1A of the second embodiment.

### Examples

Example 1 corresponding to the first embodiment and Example 2 corresponding to the second embodiment will be described below.

### Example 1

The size of each portion of the circuit module 1 is as follows. The main wiring board 2 is a two-layer printed wiring board having an arcuate shape with a cutout, and includes an insulating layer of FR-4 and wiring layers of copper formed on the front side and the back side of the insulating layer.

The main wiring board 2 has an outer radius of 32 mm, an inner radius of 22 mm, and a thickness of 0.8 mm. The angle between the radially outer corners and the arc center of the main wiring board 2 is 125°. The length W3 of the non-curved surface portion 2030 is 30 mm. The non-curved surface portion 2030 of the end surface 203 of the main wiring board 2 is a flat surface orthogonal to the main surfaces 201 and 202. The plurality of pads 11 and the plurality of 12 each have a thickness of 0.015 mm, a width of 0.125 mm, and a length of 1.0 mm. The pitch of the plurality of pads 11 in the X direction and the pitch of the plurality of pads 12 in the X direction are each 0.25 mm, the number of the plurality of pads 11 is 30, and the number of the plurality of pads 12 is 30.

Two pads 5 are formed on the main surface 201 of the main wiring board 2, and two pads 6 are formed on the main surface 202 of the main wiring board 2. The plurality of pads 11 are disposed between the two pads 5, and the plurality of pads 12 are disposed between the two pads 6. The pads 5 and the pads 6 each have a thickness of 0.015 mm, a width of 1.2 mm, and a length of 1.2 mm.

Among the electronic parts 101 mounted on the main wiring board 2, the electronic part of the smallest size is a chip part of a 3216 size (3.2 mm×1.6 mm). Among the electronic parts 101 mounted on the main wiring board 2, the electronic part of the largest size is a connector part of 20 mm×9 mm.

The sub wiring board 3 is a six-layer printed wiring board, and is constituted by a laminate of insulating layers of FR-4 and copper wiring layers.

A pad group including the plurality of pads 21 and the plurality of pads 22 is formed in a narrow protruding region of the sub wiring board 3. The narrow protruding region in which the pad group is formed on the sub wiring board 3 has a width of 13 mm, a length of 10 mm, and a thickness of 0.8 mm. The wide region in which the electronic parts are mainly mounted on the sub wiring board 3 has a width W2 of 25 mm, a length of 20 mm, and a thickness of 0.8 mm. The plurality of pads 21 and the plurality of pads 22 each have a thickness of 0.015 mm, a width of 0.125 mm, and a length of 1.0 mm. The pitch of the plurality of pads 21 in the X direction and the pitch of the plurality of pads 22 in the X direction are each 0.25 mm, the number of the plurality of pads 21 is 30, and the number of the plurality of pads 22 is 30.

Two pads 7 and two pads 8 are formed on the main surface 301 of the sub wiring board 3. The plurality of pads 21 are disposed between the two pads 7, and the plurality of pads 22 are disposed between the two pads 8. The pads 7 and the pads 8 each have a thickness of 0.015 mm, a width of 1.2 mm, and a length of 1.2 mm. The distance in the Z direction between the plurality of pads 21 and the plurality of pads 22 and the distance in the Z direction between the pads 7 and the pads 8 are each 0.8 mm.

On the main surface 301 of the sub wiring board 3, an electronic part having a maximum size of 15 mm×15 mm and two electronic parts each having a size of 5 mm×5 mm are mounted.

The plurality of pads 11 on the main wiring board 2 are respectively bonded to the plurality of pads 21 on the sub wiring board 3 via the solder 61, and the plurality of pads 12 on the main wiring board 2 are respectively bonded to the plurality of pads 22 on the sub wiring board 3 via the solder 62.

The assisting member 30 is a cubic copper chip whose sides are each 1 mm long. The assisting members 30 disposed on the main surface 201 side of the main wiring board 2 are bonded to the pads 5 and the pads 7 via the solder 31, and the assisting members 30 disposed on the main surface 202 side of the main wiring board 2 are bonded to the pads 6 and the pads 8 via the solder 32. The metal composition of the solder is Sn-3.0Ag-0.5Cu.

The length L1 of the extending portion 3011 of the sub wiring board 3 is 2.5 mm, and the length L2 of the extending portion 3012 is 26.7 mm. The length W4 of the main wiring board 2 is 10 mm. The length L4 between an end of the solder 31 and an end of the solder 32 is 3.4 mm.

The plurality of electronic parts 102 mounted on the sub wiring board 3 are not arranged such that the bonding portion between the main wiring board 2 and the sub wiring board 3 is interposed therebetween, and are arranged in an integrated manner on the extending portion 3012. The large electronic parts 102 can be disposed on the extending portion 3012 of the sub wiring board 3. The wiring connected to each of the plurality of electronic parts 102 mounted on the main surface 301 of the sub wiring board 3 is disposed on the extending portion 3012 side without extending around the main wiring board 2. In addition, since there is no need to dispose the wiring in the inner layer of the sub wiring board 3, the wiring length can be reduced, and disconnection can be reduced. In addition, restriction in wiring design is reduced, and the freedom of wiring design is increased.

As a result of the main wiring board 2 including the non-curved surface portion 2030, the main wiring board 2 can be bonded to the sub wiring board 3 in a state in which the non-curved surface portion 2030 is opposed to the main surface 301 of the sub wiring board 3. As a result of this, the lens outer diameter is not restricted, and the outer diameter of the optical device 500 does not increase. In addition, as a result of providing the assisting members 30, the inclination amount by which the main wiring board 2 is inclined with respect to a direction orthogonal to the main surface 301 of the sub wiring board 3 by a shake during transport or a hot air when solder is melted in a soldering step can be reduced, and the fillet shapes and thickness of the solders bonding the main wiring board 2 and the sub wiring board 3 to each other are less likely to vary. Therefore, the uniformity of the fillet shapes and thickness of the solders is improved, and the bonding strength of the solder bonding portion is improved.

In addition, the main wiring board 2 and a portion of the sub wiring board 3 on the extending portion 3012 side are fixed by a lens constituent part of the optical device 500 or an unillustrated rubber bush between the inner casing and the outer casing. In contrast, a portion of the sub wiring board 3 on the extending portion 3011 side cannot be fixed by a rubber bush or the like, and is in a free state. As a result of satisfying L1≤L4, the bonding strength of the solder bonding portion between the main wiring board 2 and the sub wiring board 3 increases, vibration of the extending portion 3011 side of the sub wiring board 3 is suppressed at the time of impact such as a drop of the optical device 500, and thus the reliability of the bonding by the solder bonding portion is improved.

In a state in which the solder bonding the main wiring board 2 and the sub wiring board 3 to each other is melted, the main wiring board 2 is pulled by molten solder wet-spread on the pads 5 and 7 and molten solder wet-spread on the pads 6 and 8, and a self-alignment force is generated on the main wiring board 2. As a result of this self-alignment effect, the sub wiring board 3 and the main wiring board 2 become orthogonal to or close to orthogonal to each other. As a result of this, the uniformity of the fillet shape of the solders 31, 32, 61, and 62 is improved, and the bonding strength of the solder bonding portion is improved.

### Example 2

The size of each portion of the circuit module 1A is as follows. A chip part that is a capacitor is employed as the passive part 30A. The passive part 30A is a laminate ceramic capacitor having a 2012 size (2.0 mm×1.2 mm) on respective ends of which electrodes 31A and 31B are formed. The pads 5A, 5B, 6A, and 6B each have a thickness of 0.015 mm, a width of 1.2 mm, and a length of 0.4 mm, and the distance between the electrodes 31A and 31B is 1.2 mm. The other part is substantially the same as in Example 1.

In addition, as a result of the pads 5A being separate from the pads 5B and the pads 6A being separate from the pads 6B, when the solders 31 and 32 are in a melted state, a greater force pulling the main wiring board 2A from both sides and a greater force pushing the main wiring board 2A toward the sub wiring board 3 are generated on the passive parts 30A serving as assisting members. As a result of the effect of this self-alignment force, the main wiring board 2A and the sub wiring board 3 become orthogonal to or close to orthogonal to each other. As a result of this, the uniformity of the fillet shape of the solders 31, 32, 61, and 62 is improved, and the bonding strength of the solder bonding portion is improved.

### Other Modification Examples

The present disclosure is not limited to the embodiments described above, and can be modified in many ways within the technical concept. In addition, the effects described in the present embodiment are merely enumeration of the most preferable effects, and are not limited to the present disclosure. In addition, at least two of the plurality of embodiments and the plurality of modification examples described above may be combined.

In addition, the electronic device to which the embodiments described above are applicable is not limited to the optical device described above, and the embodiments are can be also applied to, for example, information devices such as smartphones and personal computers, communication devices such as modems and routers, office appliances such as printers and copiers, medical devices such as X-ray imaging devices and endoscopes, industrial devices such as robots and semiconductor manufacturing apparatuses, and transport devices such as cars, airplanes, and ships.

In addition, the electronic parts to which the embodiments described above are applicable are not limited to the examples described above, and the embodiments described above can be also applied to, for example, image pickup devices, semiconductor devices for image processing, memory ICs, and power source ICs.

The disclosure of the present specification includes not only what is explicitly described in the present specification but also all the matter that can be grasped from the present specification and drawings attached to the present specification. In addition, the disclosure of the present specification includes a complementary set of each individual concept described in the present specification. That is, for example, in the case where the present specification includes a description of “A is B”, it can be said that the present specification discloses a concept of “A is not B” even if description of “A is not B” is omitted. This is because “A is B” is described on the premise that the case of “A is not B” has been already considered.

As described above, according to the present disclosure, a technique advantageous for realizing further high-density mounting of a large number of electronic parts can be provided.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims the benefit of Japanese Patent Application No. 2025-045660, filed Mar. 19, 2025, which is hereby incorporated by reference herein in its entirety.

What is claimed is:

1. A circuit module comprising:
a first wiring board including a first main surface and a second main surface provided on an opposite side to the first main surface; and
a second wiring board including a third main surface intersecting with a direction along the first main surface,
wherein the first main surface and the second main surface of the first wiring board are soldered to the third main surface of the second wiring board,
wherein the third main surface of the second wiring board includes an overlapping portion overlapping with the first wiring board in a first direction orthogonal to the third main surface, a first portion extending from the overlapping portion on one side in a second direction orthogonal to the first direction, and a second portion extending from the overlapping portion on another side in the second direction,
wherein W2<W1 is satisfied where W1 represents a length of the first wiring board in a third direction orthogonal to the first direction and the second direction, and W2 represents a length of the second wiring board in the third direction,
wherein L1<L2 is satisfied where L1 represents a length of the first portion in the second direction, and L2 represents a length of the second portion in the second direction, and
wherein the circuit module further comprises a plurality of electronic parts mounted on the second portion.

2. The circuit module according to claim 1, wherein the length L2 of the second portion in the second direction is equal to or more than nine times of the length L1 of the first portion in the second direction.

3. The circuit module according to claim 1,
wherein the first wiring board includes an end surface interconnecting the first main surface and the second main surface,
wherein the end surface includes a non-curved surface portion, and
wherein the non-curved surface portion of the end surface opposes the third main surface.

4. The circuit module according to claim 3, wherein the end surface includes a first curved surface portion connected to the non-curved surface portion.

5. A circuit module comprising:
a first wiring board including a first main surface, a second main surface provided on an opposite side to the first main surface, and an end surface interconnecting the first main surface and the second main surface;
a second wiring board including a third main surface intersecting with a direction along the first main surface; and
a plurality of electronic parts mounted on the third main surface,
wherein the end surface includes a non-curved surface portion and a first curved surface portion connected to the non-curved surface portion, and
wherein the first main surface and the second main surface of the first wiring board are soldered to the third main surface of the second wiring board in a state in which the non-curved surface portion is opposed to the third main surface of the second wiring board.

6. The circuit module according to claim 3, wherein the non-curved surface portion of the end surface is a flat surface portion.

7. The circuit module according to claim 3, wherein the end surface includes a second curved surface portion positioned on an opposite side to the non-curved surface portion in a first direction orthogonal to the third main surface of the second wiring board.

8. The circuit module according to claim 3, wherein W2≤W3<W1 is satisfied where W3 represents a length of the non-curved portion in the third direction.

9. The circuit module according to claim 1,
wherein the plurality of electronic parts include a first electronic part that is an integrated circuit part, and a second electronic part electrically connected to the first electronic part via wiring of the second wiring board, and
wherein the first electronic part and the second electronic part are mounted on the second portion.

10. The circuit module according to claim 9, wherein no integrated circuit part is mounted on the first portion.

11. The circuit module according to claim 9, wherein the wiring does not overlap with the first wiring board in the first direction.

12. The circuit module according to claim 9, wherein at least one of the plurality of electronic parts includes a drive circuit configured to control a motor.

13. The circuit module according to claim 1, further comprising:
a third electronic part mounted on the first wiring board,
wherein at least a portion of the third electronic part is positioned outside a region between a first virtual plane and a second virtual plane, the first virtual plane being in contact with a first end of the second wiring board in the third direction and extending in the first direction and the second direction, the second virtual plane being in contact with a second end of the second wiring board in the third direction and parallel to the first virtual plane.

14. The circuit module according to claim 1, wherein W1−W2≥L3 is satisfied where L3 represents a thickness of the first wiring board.

15. The circuit module according to claim 1, wherein L1≤L4 is satisfied where L4 represents a distance between an end of solder protruding on the one side in the second direction from the first main surface and an end of solder protruding on the other side in the second direction from the second main surface.

16. The circuit module according to claim 1, further comprising an assisting member configured to assist mechanical connection between the first wiring board and the second wiring board.

17. The circuit module according to claim 16, wherein the assisting member is a passive part.

18. An optical device comprising:
a plurality of lenses arranged along an optical axis; and
the circuit module according to claim 1.

19. The optical device according to claim 18, wherein the optical device is an interchangeable lens attachable to and detachable from a camera body.

20. The optical device according to claim 19, wherein the optical device includes a mount portion for attaching the optical device to the camera body, and the first portion is closer to the mount portion than the second portion.
